(19) United States
(12) Patent Application Publication
(10) Pub. No.: US 2012/0169972 A1
(43) Pub. Date: Jul. 5, 2012

(54) LIQUID CRYSTAL DISPLAY PANEL AND APPARATUS INCLUDING THE SAME

(75) Inventors: Il-yong JUNG, Yongin-si (KR); Kun-ho CHO, Suwon-si (KR); Myung-ryul JUNG, Hwaseong-si (KR); Ju-seong HWANG, Cheonan-si (KR)

(73) Assignee: SAMSUNG ELECTRONICS CO., LTD., Suwon-si (KR)

(21) Appl. No.: 13/244,491

(22) Filed: Sep. 25, 2011

(30) Foreign Application Priority Data
Dec. 29, 2010 (KR) 10-2010-0137768

(51) Int. Cl. G02F 1/1335; H01L 33/08

(52) U.S. Cl. 349/96; 438/30; 257/E33.012

(57) ABSTRACT

Provided are a liquid crystal display panel and an apparatus including the same, the liquid crystal display panel including: a first substrate which includes a first incident surface to receive light and a first emission surface to emit the light; a second substrate which includes a second incident surface to receive the light from the first emission surface of the first substrate, and a second emission surface to emit the light from the second incident surface, and spaced from the first substrate at an interval; a liquid crystal layer disposed between the first substrate and the second substrate; and a wire grid layer which is disposed in at least one of the first substrate and the second substrate and focuses and polarizes the light.

### CROSS-REFERENCE TO RELATED APPLICATION

This application claims priority from Korean Patent Application No. 10-2010-0137768, filed on Dec. 29, 2010 in the Korean Intellectual Property Office, the disclosure of which is incorporated herein by reference.

### BACKGROUND

1. Field

Apparatuses consistent with exemplary embodiments relate to a liquid crystal display panel and an apparatus including the same, and more particularly, to a liquid crystal display panel and an apparatus including the same which has a thinner thickness and has a simplified manufacturing process.

2. Description of the Related Art

Flat display panels such as liquid crystal display (LCD) apparatuses, plasma display panels (PDPs), and organic light emitting diodes (OLEDs) have replaced conventional cathode ray tubes (CRTs).

Among others, the LCD apparatuses include a first substrate including a thin film transistor (TFT), a second substrate including a color filter and liquid crystals disposed between the first and second substrates. The liquid crystals do not emit light themselves and thus require a backlight unit to supply light thereto.

The backlight unit is classified into an edge type and a direct type according to a location of a light source. The edge type backlight unit has good light uniformity and long life and is advantageous for making a thin LCD apparatus. However, the edge type requires a light guide plate to uniformly emit light from the lateral side of the backlight unit to the liquid crystals. Such light guide plate increases an entire thickness of the LCD panel.

The LCD apparatus further includes polarizers which are disposed in external opposite sides of the LCD panel to improve light efficiency. Such polarizers have less polarizing efficiency at high temperature and high humidity. Also, an additional process should be performed after the manufacturing process of the LCD panel to install the polarizers in the external opposite sides of the LCD panel.

### SUMMARY

One or more exemplary embodiments provide a liquid crystal display panel and an apparatus including the same having a thinner thickness.

One or more exemplary embodiments also provide a liquid crystal display panel and an apparatus including the same which have a simplified manufacturing process.

According to an aspect of an exemplary embodiment, there is provided a liquid crystal display panel including: a first substrate which includes a first incident surface to receive light and a first emission surface to emit light; a second substrate which includes a second incident surface to receive light from the first emission surface of the first substrate, and a second emission surface to emit light from the second incident surface, and is spaced from the first substrate at an interval; a liquid crystal layer disposed between the first substrate and the second substrate; and a wire grid layer which is disposed on at least one of the first substrate and the second substrate and focuses and polarizes the light.

The first substrate may be provided to guide the received light through the first incident surface to the liquid crystal layer.

The wire grid layer may include a first wire grid layer disposed on one of the first incident surface and the first emission surface of the first substrate; and a second wire grid layer which is disposed on one of the second incident surface and the second emission surface of the second substrate.

The first wire grid layer may be disposed on the first emission surface provided between the first substrate and the liquid crystal layer.

The second wire grid layer may be disposed on the second incident surface provided between the second substrate and the liquid crystal layer.

The wire grid layer may include one of aluminum, silver, copper, molybdenum, tantalum, tin, nickel, indium, magnesium, iron, chrome and silicon or an alloy including at least two of the foregoing.

According to an aspect of another exemplary embodiment, there is provided a liquid crystal display apparatus including: a liquid crystal display panel which includes a first substrate including a first incident surface to receive light and a first emission surface to emit light, a second substrate which includes a second incident surface to receive light from the first emission surface of the first substrate and a second emission surface to emit light from the second incident surface, and is spaced apart from the first substrate, a liquid crystal layer which is provided between the first substrate and the second substrate, and a wire grid layer which is disposed in at least one of the first substrate and the second substrate and polarizes and focuses the light; and a light source which emits light to the first incident surface of the first substrate.

The first substrate may guide light from the first incident surface to the liquid crystal layer.

The wire grid layer may include a first wire grid layer which is disposed on one of the first incident surface and the first emission surface of the first substrate; and a second wire grid layer which is disposed on one of the second incident surface and the second emission surface of the second substrate.

The first wire grid layer may be disposed on the first emission surface provided between the first substrate and the liquid crystal layer.

The second wire grid layer may be disposed on the second incident surface provided between the second substrate and the liquid crystal layer.

The wire grid layer may include one of aluminum, silver, gold, copper, molybdenum, tantalum, tin, nickel, indium, iron, chrome and silicon or an alloy including at least two of the foregoing.

The light source may include one of a light emitting diode (LED), incandescent lamp, and a cold cathode fluorescent lamp (CCFL) or a combination of at least two of the foregoing.

### BRIEF DESCRIPTION OF THE DRAWINGS

The above and/or other aspects will become apparent and more readily appreciated from the following description of the exemplary embodiments, taken in conjunction with the accompanying drawings, in which:

FIG. 1 is a block diagram of an LCD apparatus according to an exemplary embodiment;

FIG. 2 is a sectional view of an LCD panel according to an exemplary embodiment;

FIG. 3 is an exploded perspective view of the LCD panel according to an exemplary embodiment;

FIG. 4 is a perspective view of a first substrate in which a first wire grid layer is disposed;

FIG. 5 is a perspective view of a second substrate in which a second wire grid layer is disposed;

FIG. 6 explains an optical progress path of light emitted into the first substrate; and

FIG. 7 is a sectional view of an LCD panel according to another exemplary embodiment.

### DETAILED DESCRIPTION OF EXEMPLARY EMBODIMENTS

Below, exemplary embodiments will be described in detail with reference to accompanying drawings so as to be easily realized by a person having ordinary knowledge in the art. The exemplary embodiments may be embodied in various forms without being limited to the exemplary embodiments set forth herein. Descriptions of well-known parts are omitted for clarity, and like reference numerals refer to like elements throughout.

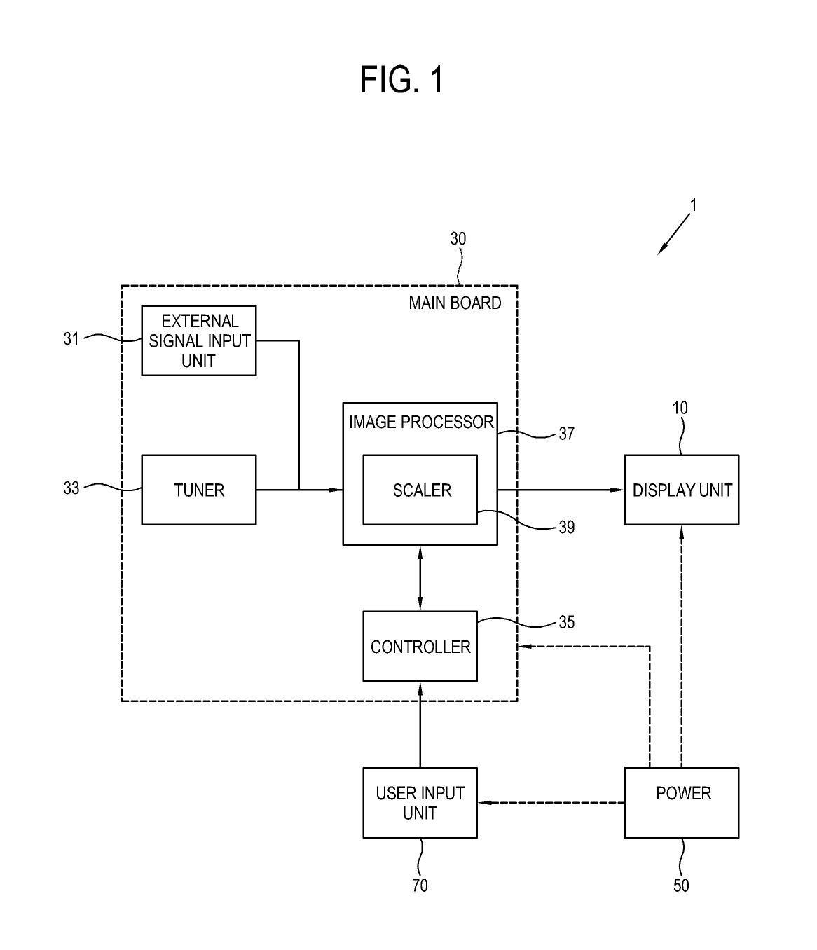

FIG. 1 is a block diagram of an LCD apparatus 1 according to an exemplary embodiment.

As shown therein, the LCD apparatus 1 according to an exemplary embodiment may include an external signal input unit 31, a tuner 33, an image processor 37, a controller 35, a user input unit 70, a power source unit 50 and a display unit 10.

The image processor 37 processes an image signal received from the tuner 33 to display the image signal on the display unit 10. The image processor 37 may further include a scaler 39 to output an image signal scaled according to a resolution of the display unit 10.

The tuner 33 and the external signal input unit 31 are mounted in a main board 30. The image processor 37 which processes an image signal input from the tuner 33 or the external signal input unit 31; and the controller 35 which controls the image processor 37 may be provided in the main board 30.

The power source unit 50 may supply power to the user input unit 70, the main board 30 and the display unit 10.

The display unit 10 displays an image by using the image signal received from the image processor 37. The display unit 10 may include an LCD panel 100, and a light source 90 which supplies light to the LCD panel 100.

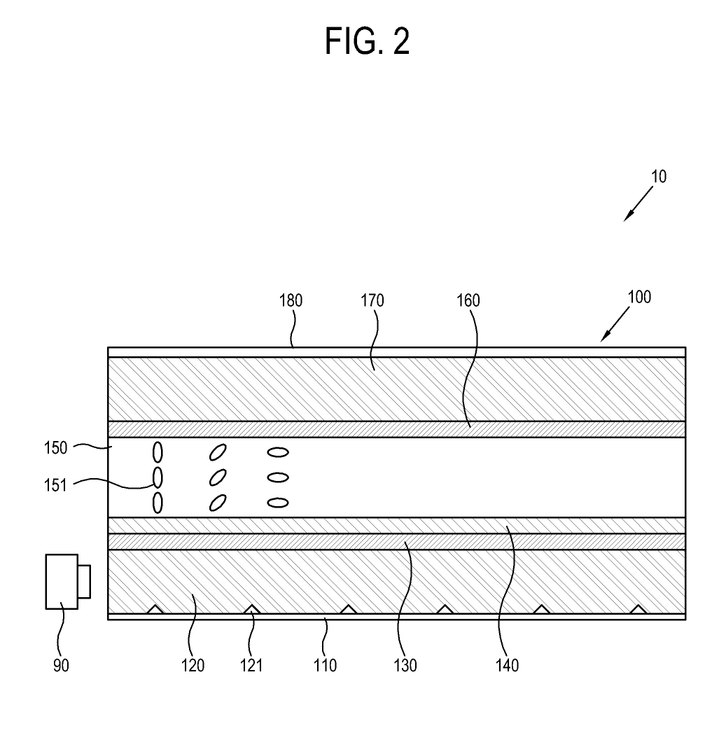

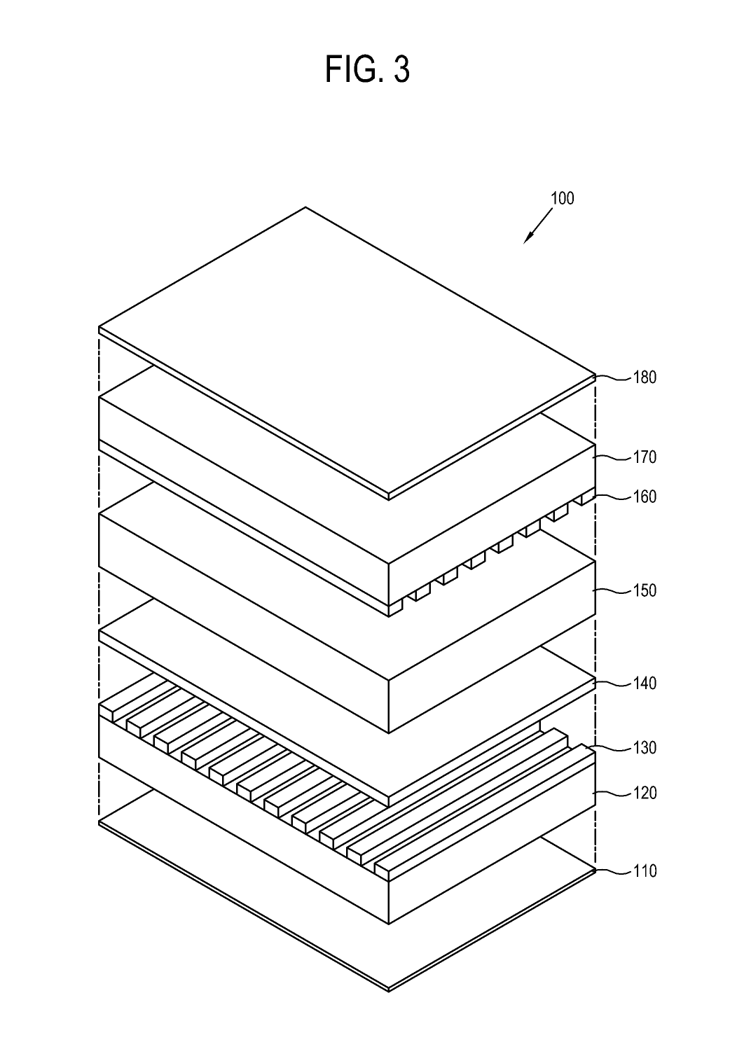

FIG. 2 is a sectional view of the LCD panel 100 according to an exemplary embodiment. FIG. 3 is an exploded perspective view of the LCD panel 100.

The LCD panel 100 includes a first substrate 120 and a second substrate 170 which are spaced from each other, a liquid crystal layer 150 which is disposed between the first and second substrates 120 and 170, a wire grid layer 130 and 160 which is disposed in at least one of the first and second substrates 120 and 170, and a TFT 140 which changes an arrangement of liquid crystals.

As the liquid crystals are passive light emitting elements, the LCD apparatus according to an exemplary embodiment further includes the light source 90. Other than those shown in FIG. 2, the LCD panel 100 may further include an optical sheet such as a protection film (not shown) and an adhesive film (not shown).

The first and second substrates 120 and 170 include an insulating material to form a conductive pattern (not shown) thereon. The material may include a light transmissive transparent substrate, and more preferably, may include glass.

The conductive pattern which is formed on the surface of the first and second substrates 120 and 170 may include oxide such as indium-tin oxide (ITO) or antimony tin oxide (ATO).

The conductive pattern may be formed by sputtering or deposition. The sputtering is a process whereby atoms of oxide are ejected from a solid target material due to bombardment of the target by energetic particles to thereby hold the atoms of oxide to the surface of the transparent substrate.

The first substrate 120 includes a first incident surface to receive light, a first emission surface to emit light from the first incident surface. The light which passes through the first incident surface is directed to the liquid crystal layer 150.

The second substrate 170 faces the first substrate 120, and the liquid crystal layer 150 is disposed therebetween. The second substrate 170 includes a second incident surface which receives light from the liquid crystal layer 150, and a second emission surface which emits light from the second incident surface.

A plurality of gate wirings (not shown) and a plurality of data wirings (not shown) are formed in a matrix in the first substrate 120. At an intersection of the gate wirings and the data wirings, a pixel electrode (not shown) and the thin film transistor (TFT) 140 are formed. A signal voltage which is applied through the TFT 140 is supplied to the liquid crystals by the pixel electrode. The liquid crystals are arranged by the signal voltage and have a light transmittivity set.

The TFT 140 may be disposed between the liquid crystal layer 150 and the second substrate 170 as applicable. That is, the TFT 140 may be disposed on a surface from which light from the liquid crystal layer 150 is emitted.

The first substrate 120 may include a pattern 121 to guide light to the liquid crystal layer 150.

As shown in FIG. 2, the pattern 121 may be shaped like a pyramid. In this case, the incident light collides with the front surface of the pyramid to cause total reflection, and then is guided to the liquid crystal layer 150. If the light is directed to the front surface of the pyramid at an angle smaller than a critical angle, the light is directed to the inside of the pyramid and discharged to the rear side of the pyramid. That is, the light which goes up by the pattern 121 has a brightness improved and the light which is reflected again or passes through the pattern 121 improves uniformity of brightness.

Accordingly, the first substrate 120 efficiently focuses light from the light source 90, and guides such light to the liquid crystal layer 150 in addition to supporting the liquid crystal layer 150.

Since the first substrate 120 focuses and guides light, the light guide plate and the optical sheet are omitted to thereby make a thinner LCD panel.

The first substrate 120 may further include a mirror coating layer 110 on a surface facing the surface emitting light to the liquid crystal layer 150. The mirror coating layer 110 reflects part of the light directed to the first substrate 120 to the liquid crystal layer 150.

The liquid crystal layer 150 is disposed between the first substrate 120 and the second substrate 170, and is filled with liquid crystals therein. As shown in FIG. 2, the liquid crystal layer 150 has liquid crystal cells 151 arranged in a matrix in pixels. The liquid crystal cells 151 have their arrangement changed by image signal information to adjust light transmittivity and form an image.

The liquid crystals may be classified into three types depending on an arrangement method of molecules. If an axial direction is uniform, such liquid crystals are called a nematic phase. If molecules in a certain direction form a layer, such liquid crystals are called a smectic phase, and molecules in a changing direction are called a cholesteric phase.

The first and second substrates 120 and 170 which are disposed at opposite sides, having the liquid crystal layer 150 disposed therebetween, include at least one of wire grid layers 130 and 160.

The wire grid layers 130 and 160 act as a conventional polarizer. The wire grid layers 130 and 160 focus light on behalf of a conventional double brightness enhancement film (DBEF).

The wire grid layers 130 and 160 may be formed by (i) depositing a metal thin film on a substrate, (ii) applying polymer including a heat curing material or a UV curing material on the metal thin film, (iii) transferring a minute pattern on a surface of the polymer and (iv) etching the polymer and metal thin film using the minute pattern as a mask.

The material of the metal thin film may include aluminum, silver, gold, copper, molybdenum, tantalum, tin, nickel, indium, magnesium, iron, chrome, silicon, or an alloy of the foregoing.

A related art absorbing polarizer has 50% of light pass therethrogh and absorbs the remainder of light, causing light loss. However, the wire grid layers 130 and 160 include a metal material, and reflect S-polarizing light and have a P-polarizing light pass therethrough. Accordingly, utilization of the reflected S-polarizing light may raise light usage efficiency close to 100%.

If the related art absorbing polarizer is exposed to a high-brightness light source, it becomes unstable due to thermal deformation of a dielectric substance. However, the wire grid layers 130 and 160 are metal layers formed on a transparent substrate, and thus are stable even if exposed to the high-brightness light source.

The wire grid layers 130 and 160 have a simple process and may be manufactured in bulk, and are applicable to large-size LCD panels.

While the conventional polarizer is disposed on an external side of the LCD panel, the wire grid layers 130 and 160 are disposed on an internal side of the LCD panel 100. Accordingly, an optical sheet such as a reflection film is omitted to make a thinner LCD panel.

As the wire grid layers 130 and 160 may be coated on the substrate instead of being attached thereto, an adhesive film may be omitted.

As the wire grid layers 130 and 160 are disposed on the internal side of the LCD panel 100, the LCD panel may be manufactured by a single process without any additional process.

The LCD panel 100 according to an exemplary embodiment in FIG. 2 may be disposed together with the light source 90 to form an LCD apparatus 10. The LCD apparatus 10 may be used in a monitor, a screen of a mobile phone and other various display apparatuses.

The light source 90 of the LCD apparatus 10 may include a CCFL, a hot cathode fluorescent lamp (HCFL), an external electrode fluorescent lamp (EEFL) and a LED. A light source cover (not shown) may be disposed on an external side of the light source 90.

As described above, the LCD panel 100 according to an exemplary embodiment does not have a polarizer and a light guide plate, and thus is thinner in thickness.

If the thickness of the LCD panel according to an exemplary embodiment is thinner, an entire weight of the LCD panel may be lighter. Also, the omission of the polarizer and the light guide plate may reduce manufacturing costs. Also, cross talk may be reduced by a decrease in a difference of paths according to introduction and emission of light.

FIG. 3 is an exploded perspective view of the LCD panel 100 in FIG. 2. As shown therein, a grid direction of the first wire grid layer 130 may be perpendicular to a grid direction of the second wire grid layer 160.

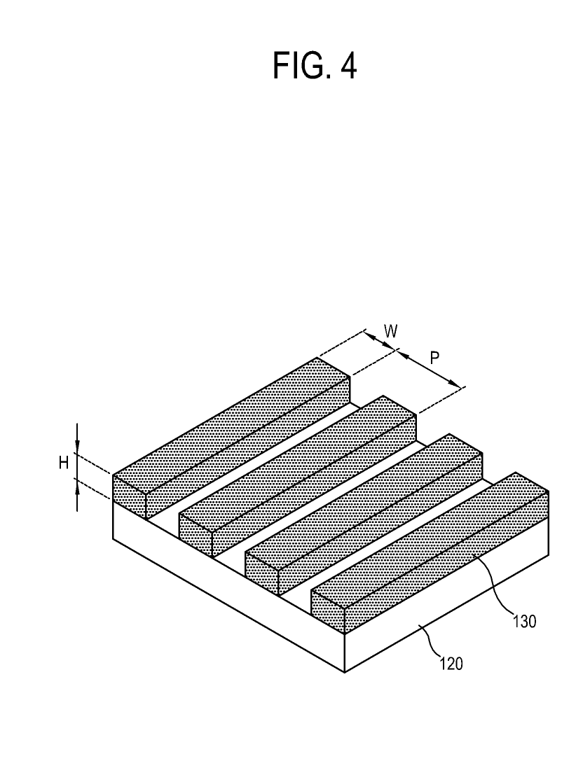

FIG. 4 illustrates the first substrate 120 and the first wire grid layer 130 which is attached to the first substrate 120 of the LCD panel according to an exemplary embodiment.

As explained above, the first wire grid later 130 is formed by etching the metal layer deposited on the first substrate 120, and the description is the same as above, and will not be repeated. Hereinafter, the structure of the first wire grid layer 130 will be described.

The first wire grid layer 130 is formed of a transparent first substrate 120 and a metal wire grid layer is formed in a stripe pattern on the first substrate 120.

The wire grid layer has a predetermined height H, width W and a grid period P, which may vary depending on optical design. Generally, the wire grid layer has a plurality of metal grids formed in parallel in a rectangular section in a lateral side of the first substrate 120 which is light transmittive as shown in FIG. 4.

Generally, if the grid period P has a higher value than a wavelength of light, the incident light is divided into a plurality of diffraction light. If the grid period P is a half or less than a half of a wavelength of the incident light, such light is divided into an S-polarizing light and P-polarizing light instead of being divided into a plurality of diffraction light.

The first substrate 120 may have various shapes including a plate, sheet, and a film, and may be bent.

The material of the first substrate 120 may include glass, acryl resin, polyester resin, polyethylene terephthalate, polycarbonate, cyclo olefin polymer, cyclo olefin copolymer (COC), norbonene resin, polyimide resin or the like.

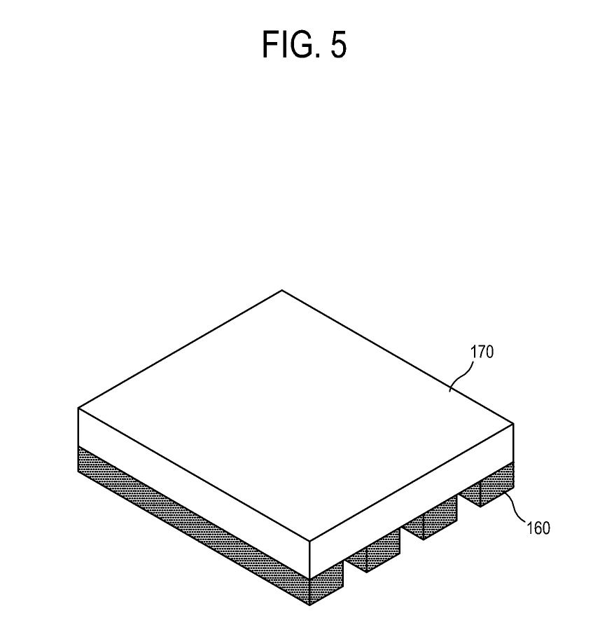

FIG. 5 illustrates the second wire grid layer 160 which is formed on a location facing the first wire grid layer 130, with the liquid crystal layer 150 therebetween, and the second substrate 170 in which the second wire grid layer 150 is formed.

The forming method and structure of the second wire grid layer 160 is the same as those of the first wire grid layer 130, and a detailed description will be omitted. However, a grid of the second wire grid layer 160 is perpendicular to a grid of the first wire grid layer 130. The locations of the first and second wire grid layers 130 and 160 may change to each other.

As shown in FIG. 4, the first wire grid layer 130 allows particular polarizing light among light generated by the light source 90 to pass therethrough, and blocks the remaining polarizing light. The light which passes through the first wire grid layer 130 has a polarizing direction set for each pixel according to the driving state of the pixels, and progresses to the second wire grid layer 160.

The second wire grid layer 160 allows light in a predetermined polarizing direction to pass therethrough, and blocks the remaining light. Accordingly, the LCD panel blocks light that passes through part of pixels and allows light which has passed through other pixels, to pass therethrough according to the driving state of the liquid crystals and form an image.

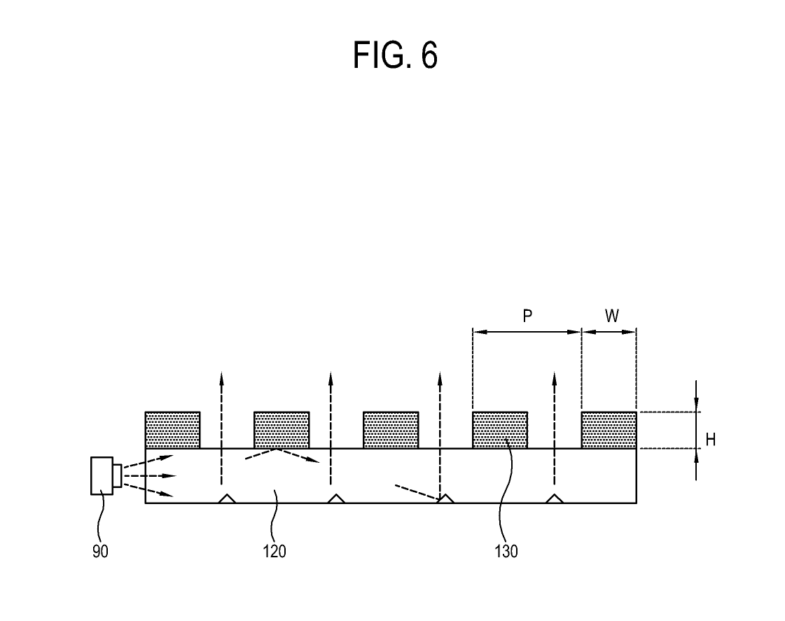

FIG. 6 illustrates light that is travels through the first incident surface and is emitted to the first emission surface of the first substrate 120.

Among the incident light, the P-polarizing light passes through the grid and is emitted to the liquid crystal layer 150. The S-polarizing light is reflected in the grid. The reflected light is reflected by the pattern 121 again, and is emitted as a P-polarizing light.

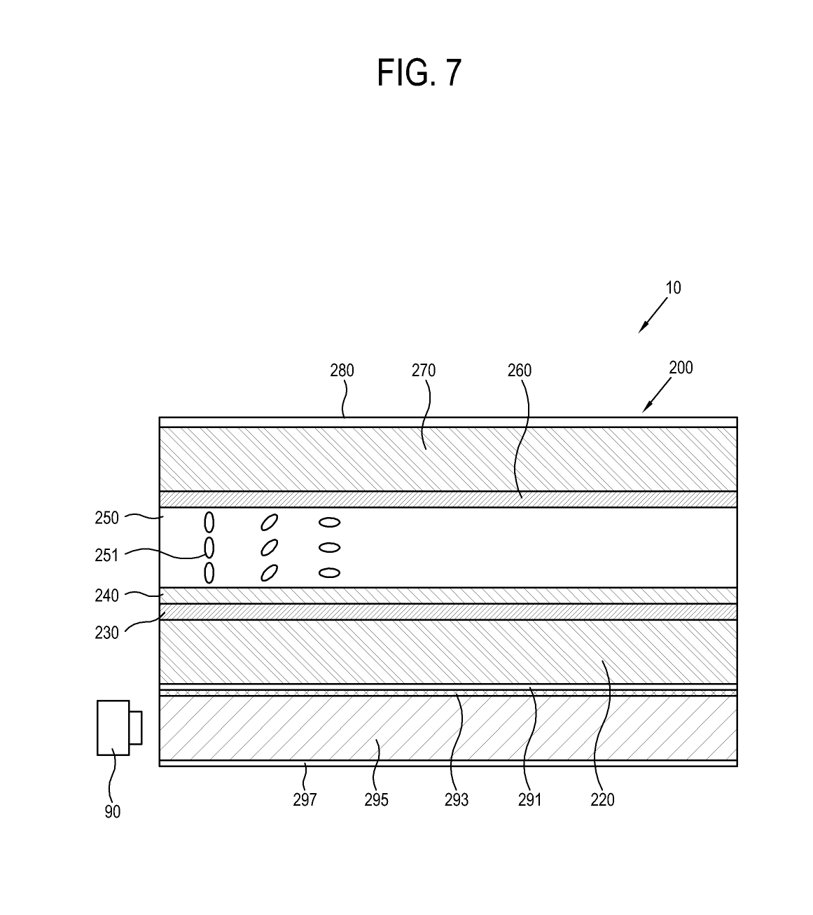

FIG. 7 is a sectional view of an LCD panel 200 according to another exemplary embodiment.

As shown in FIG. 7, the LCD panel 200 includes a pair of substrates 220 and 270, a liquid crystal layer 250 is disposed between the substrates 220 and 270, a TFT 240 providing an electric signal to the liquid crystal layer 250, and wire grid layers 230 and 260 disposed in the substrates 220 and 270. Other than those shown in FIG. 7, the LCD panel 200 may further include an optical sheet such as a protection film and an adhesive film.

Hereinafter, only features of the other exemplary embodiment will be described, and the repetitive description will be omitted.

The LCD panel 200 according to the other exemplary embodiment further includes a light guide plate 295 which guides light from the light source 90 to the liquid crystal layer 250. The LCD panel 200 further includes a reflector 297 which is disposed on a lower part of the light guide late 295 and which reflects part of light to the light guide plate 295, and a diffuser 293 which is disposed in an upper part of the light guide plate 295 and diffuses light from the light guide plate 295. The LCD panel 200 further includes a prism 291 which focuses light to increase brightness.

The LCD panel 200 may exclude a mirror coating layer 110 and a pattern 121.

As described above, a liquid crystal display panel and an apparatus including the same according to the exemplary embodiments have the following effects:
(i) a light guide plate and an optical sheet are omitted to thereby reduce an entire thickness of the LCD apparatus; and
(ii) a wire grid layer replaces a polarizer to thereby simplify the manufacturing process of the LCD panel and an apparatus including the same.

Although a few exemplary embodiments have been shown and described, it will be appreciated by those skilled in the art that changes may be made in these exemplary embodiments without departing from the principles and spirit of the inventive concept, the range of which is defined in the appended claims and their equivalents.

What is claimed is:

1. A liquid crystal display panel comprising:
a first substrate which comprises a first incident surface to receive light and a first emission surface to emit the light;
a second substrate which comprises a second incident surface to receive the light emitted from the first emission surface of the first substrate, and a second emission surface to emit the light received by the second incident surface, the second substrate being spaced apart from the first substrate;
a liquid crystal layer disposed between the first substrate and the second substrate; and
a wire grid layer which is disposed on at least one of the first substrate and the second substrate and focuses and polarizes the light.

2. The liquid crystal display panel according to claim 1, wherein the first substrate guides the light received through the first incident surface to the liquid crystal layer.

3. The liquid crystal display panel according to claim 1, wherein the wire grid layer comprises a first wire grid layer which is disposed on one of the first incident surface and the first emission surface of the first substrate; and
a second wire grid layer which is disposed on one of the second incident surface and the second emission surface of the second substrate.

4. The liquid crystal display panel according to claim 3, wherein the first wire grid layer is disposed on the first emission surface provided between the first substrate and the liquid crystal layer.

5. The liquid crystal display panel according to claim 3, wherein the second wire grid layer is disposed on the second incident surface provided between the second substrate and the liquid crystal layer.

6. The liquid crystal display panel according to claim 1, wherein the wire grid layer comprises one of aluminum, silver, copper, molybdenum, tantalum, tin, nickel, indium, magnesium, iron, chrome and silicon or an alloy comprising at least two of the foregoing.

7. A liquid crystal display apparatus comprising:
a liquid crystal display panel which comprises:
a first substrate comprising a first incident surface to receive light and a first emission surface to emit the light,
a second substrate which comprises a second incident surface to receive the light emitted from the first emission surface of the first substrate and a second emission surface to emit the light received by the second incident surface, is the second substrate being spaced apart from the first substrate,
a liquid crystal layer disposed between the first substrate and the second substrate, and
a wire grid layer which is disposed on at least one of the first substrate and the second substrate and polarizes and focuses the light; and
a light source which emits light to the first incident surface of the first substrate.

8. The liquid crystal display apparatus according to claim 7, wherein the first substrate guides the light received by the first incident surface to the liquid crystal layer.

9. The liquid crystal display apparatus according to claim 7, wherein the wire grid layer comprises a first wire grid layer which is disposed on one of the first incident surface and the first emission surface of the first substrate; and
a second wire grid layer which is disposed on one of the second incident surface and the second emission surface of the second substrate.

10. The liquid crystal display apparatus according to claim 7, wherein the first wire grid layer is disposed on the first emission surface provided between the first substrate and the liquid crystal layer.

11. The liquid crystal display apparatus according to claim 7, wherein the second wire grid layer is disposed on the second incident surface provided between the second substrate and the liquid crystal layer.

12. The liquid crystal display apparatus according to claim 7, wherein the wire grid layer comprises one of aluminum, silver, gold, copper, molybdenum, tantalum, tin, nickel, indium, iron, chrome and silicon or an alloy comprising at least two of the foregoing.

13. The liquid crystal display apparatus according to claim 7, wherein the light source comprises one of a light emitting diode (LED), incandescent lamp, and a cold cathode fluorescent lamp (CCFL) or a combination of at least two of the foregoing.

14. A liquid crystal display panel comprising:
a first substrate;
a second substrate spaced apart from the first substrate;
a liquid crystal layer disposed between the first substrate and the second substrate; and
a first wire grid layer disposed on a surface of the first substrate facing the second substrate and a second wire grid layer formed on a surface of the second substrate facing the first substrate,
wherein the first and second wire grid layers focus and polarize light.

15. The liquid crystal display apparatus according to claim 14, wherein the first substrate comprises a pattern to guide the light to the liquid crystal layer.

16. The liquid crystal display apparatus according to claim 14, wherein the first and second wire grid layers have a stripe pattern.

17. The liquid crystal display apparatus according to claim 16, wherein the first wire grid layer disposed on the surface of the first substrate is perpendicular to the second wire grid layer disposed on the surface of the second substrate.

18. The liquid crystal display panel according to claim 14, wherein the first and second wire grid layers comprises one of aluminum, silver, copper, molybdenum, tantalum, tin, nickel, indium, magnesium, iron, chrome and silicon or an alloy comprising at least two of the foregoing.

19. A method of forming a wire grid layer on a substrate of a liquid crystal display (LCD) panel, the method comprising:
depositing a metal thin film on the substrate,
applying a polymer including a heat curing material or a UV curing material on the metal thin film,
transferring a minute pattern onto a surface of the polymer and
etching the polymer and metal thin film using the minute pattern as a mask forming the wire grid layer on the substrate of the LCD panel.
